(19) United States
(12) Patent Application Publication
(10) Pub. No.: US 2017/0215290 A1
(43) Pub. Date: Jul. 27, 2017

(54) REDUCED BEZEL DISPLAY DEVICE

(71) Applicant: Microsoft Technology Licensing, LLC, Redmond, WA (US)

(72) Inventors: Steven Bathiche, Kirkland, WA (US); Rajesh Manohar Dighde, Redmond, WA (US)

(73) Assignee: Microsoft Technology Licensing, LLC, Redmond, WA (US)

(21) Appl. No.: 15/004,640

(22) Filed: Jan. 22, 2016

(51) Int. Cl. H05K 5/00

(52) U.S. Cl. CPC H05K 5/0017

(57) ABSTRACT

Examples are disclosed herein that relate to display devices. One example provides a display device comprising a chassis including a ledge surrounding an aperture, a cover layer positioned in the aperture, and a display layer attached to the cover layer, the display layer having a perimeter portion extending beyond an outer edge of the cover layer and positioned below an underside of the ledge.

### BACKGROUND

A typical display device includes an active display area operable to output visible imagery and a non-active display area in which display electronics are disposed. A structure such as a black mask may be positioned over the non-active display area to render the display electronics imperceptible.

### SUMMARY

Examples are disclosed herein that relate to display devices. One example provides a display device comprising a chassis including a ledge surrounding an aperture, a cover layer positioned in the aperture, and a display layer attached to the cover layer, the display layer having a perimeter portion extending beyond an outer edge of the cover layer and positioned below an underside of the ledge.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 shows an example display device implemented in a mobile computing device.

FIG. 2 shows a cross-sectional view of an example display device.

FIG. 3 shows a cross-sectional view of another example display device.

FIG. 4 shows a flowchart illustrating an example method of manufacturing a display device.

### DETAILED DESCRIPTION

As described above, a typical display device may include an active display area, in which pixels or other display elements operate to produce visible imagery, and a non-active display area in which display electronics that drive operation of the display elements are disposed. The non-active display area may occupy a perimeter portion of the display device—e.g., the perimeter portion may surround the active display area. Typically, a structure such as a black mask is used to conceal the non-active display area so that the display electronics disposed therein are imperceptible to users. The concealment of display electronics may increase the aesthetic quality of a display device, as their appearance may be considered undesirable and in visual contrast to the active display area, whose maximization may correlate to aesthetic quality as well.

While the use of a black mask may effectively render display electronics imperceptible, the increase in aesthetic quality due to its inclusion may be limited by the device chassis portion required to support the black mask. In a typical implementation, a recess is formed in a display device chassis in which an adhesive is disposed. A black mask is then positioned in the recess on top of the adhesive and is thus adhered to the chassis. Other components, such as a cover layer and a display layer, are suspended in the chassis and supported by the black mask through their direct or intermediate attachment to the black mask. As such, a minimum recess size is required to support the black mask and display components. This in turn imposes a minimum bezel width—e.g., the distance between an outer edge of the active display area to an outer edge of a device chassis—on a display device, which may limit the overall aesthetic quality of the display device by surrounding the active display area with a highly perceptible non-active display area.

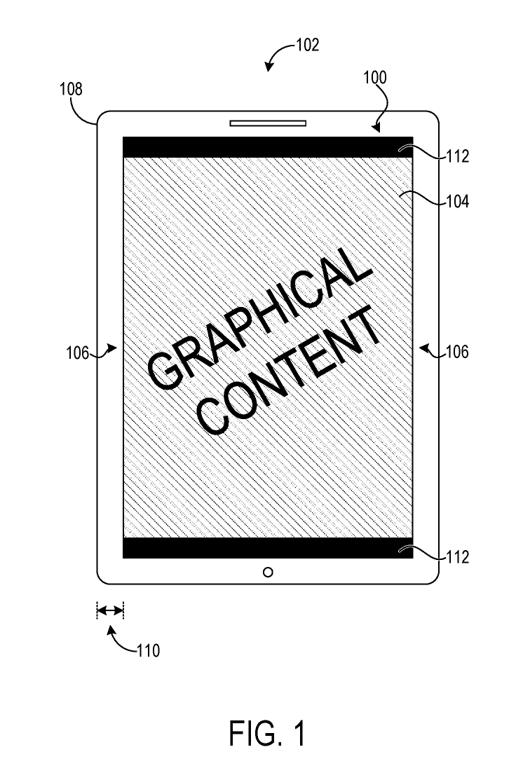

To address the issues described above, implementations are described herein for providing a display device that reduces or eliminates the use of a black mask or other dedicated concealing structures. FIG. 1 shows a display device 100 implemented in a mobile computing device 102, which may assume the form of a smartphone, tablet computing device, etc. However, display device 100 may be implemented in any suitable type of computing device, in combination with other suitable devices (e.g., touch sensors), or as a display device alone without being combined with other device types.

Display device 100 includes an active display area 104 in which the display device is operable to output graphical content. A plurality of display elements such as pixels in active display area 104 may be driven by display electronics to produce graphical content. Conversely, the display electronics may be positioned outside of active display area 104 in a non-active display area, which is partially represented at locations 106 corresponding to the left and right sides of mobile computing device 102. Here, a chassis 108, which forms at least a portion of the housing of mobile computing device 102, is leveraged to conceal the display electronics to the left and right of active display area 104. As a result, a black mask or other structure that might otherwise be used to conceal underlying components at this location may be omitted. Further, some or all of the portion of chassis 108 used to conceal the display electronics may be a chassis portion formed even had a concealing structure been used. The omission of a concealing structure and use of an existing chassis portion to conceal display electronics may individually or cooperatively reduce a bezel width 110 of mobile computing device 102, which may increase the aesthetic quality of the mobile computing device and display device 100. As shown in FIG. 1, bezel width 110 may correspond to the distance between an outer edge of active display area 104 and an outer edge of chassis 108—e.g., as viewed from a direction perpendicular to the plane of the active display area.

In some implementations, both a device chassis and a concealing structure may be used to conceal a non-active display area. As an example, FIG. 1 shows the use of a black mask 112 to conceal underlying display electronics in the non-active display area along the top and bottom edges of active display area 104. Other configurations are possible, however. For example, a concealing structure may be used along one, two, three, four, or any suitable number of active display region edges, with a device chassis used as the concealing structure along any remaining edges not utilizing the concealing structure. Alternatively or additionally, a concealing structure may be used along portions, and not the entirety, of edges.

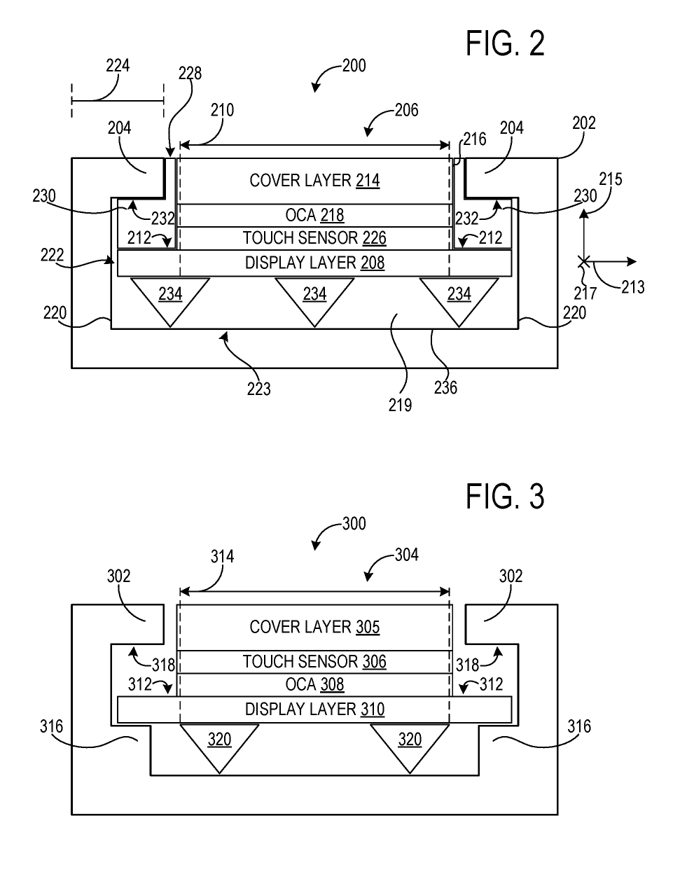

FIG. 2 shows a cross-sectional view of a display device 200. As described below, display device 200 may include components for implementing functionality other than display output—e.g., the display device may include a processor and memory for implementing a computing device such as mobile computing device 102 of FIG. 1.

Display device 200 includes a chassis 202 that at least partially provides a housing for the display device and at least partially encloses the components therein. Chassis 202 may include and/or be formed from any suitable material(s) including but not limited to metals and plastics. At a top region of display device 200, chassis 202 includes a ledge 204 surrounding an aperture 206. Ledge 204 may be used to conceal underlying display electronics in a display layer 208 and to potentially support components in display device 200. Display layer 208 includes an active display area 210 operable to output visible imagery, and a non-active display area 212 comprising display electronics that drive the display elements in the active display area. As may be seen in FIG. 2, ledge 204 may render non-active display area 212 and the display electronics therein imperceptible in a range of angles from which display device 200 is perceived during typical use. Non-active display area 212 may occupy a perimeter portion (e.g., one or more outer edges) of display layer 208 as shown in FIG. 2, but in other examples may occupy any suitable display layer region. As described in further detail below, display layer 208 may be inserted through aperture 206 at an oblique angle relative to a horizontal axis 213 of chassis 202 and a vertical axis 215 of the chassis, and then leveled. In another example, display layer 208 may be inserted through aperture 206 in a longitudinal direction 217 through a cavity 219 of chassis 202, where the cavity may be defined by side walls 220 and a bottom 223 of the chassis.

Display layer 208 may employ any suitable display technologies. For example, display layer 208 may be a liquid-crystal display (LCD). As another example, display layer 208 may be an organic light-emitting diode (OLED) display. In such implementations, the OLED display may be flexible, allowing the OLED display to be at least partially non-planar—e.g., the OLED display may be wrapped along a portion of side walls 220 of chassis 202, potentially along with other components such as a touch sensor. Further, use of an OLED display may facilitate a reduced gap between the display and chassis relative to display devices that incorporate other display types. To this end, FIG. 2 shows a display-chassis gap 222 between an outer edge of display layer 208 and an inner edge of chassis 202 whose width may be relatively low, as the OLED display incorporated in the display layer 208 may be relatively resilient to shock and forces, and able to withstand deflection into the inner edge of the chassis. The use of an OLED may thus aid in providing a reduced bezel width 224. Implementations are possible, however, in which an LCD is used in combination with a minimal display-chassis gap.

A variety of components may be positioned in and/or through aperture 206. For example, FIG. 2 shows the inclusion of a cover layer 214 positioned in aperture 206. Cover layer 214 may be optically transmissive, and in some implementations may be configured to receive touch input. Cover layer 214 may include or be formed from plastics, glass, or any other suitable material. The perimeter portion of display layer 208 may extend beyond an outer edge 216 of cover layer 214, which, in combination with ledge 204, may render non-active display area 212 imperceptible.

Display layer 208 may be attached to cover layer 214 via direct or intermediate connection. As an example, FIG. 2 shows the inclusion of an optically clear adhesive (OCA) 218 that optically and physically bonds display layer 208 to cover layer 214. OCA 218 may comprise any suitable materials (e.g., glass) and may transmit substantially all (e.g., 99%) incident light. Other configurations are possible, however, including those in which an air gap is used in lieu of OCA 218.

Components for providing functionality other than display output may be included in display device 200. As an example, FIG. 2 shows the inclusion of a touch sensor 226 in display device 200. Touch sensor 226 may comprise a discrete touch sensor layer separate from other layers in display device as shown in FIG. 2. Other configurations are possible, however, including those in which display layer 208 is an on-glass touch sensor, is laminated to glass, is provided internally to a liquid crystal layer, and is provided as an in-cell or on-cell touch sensor. When configured as a discrete touch sensor, touch sensor 226 may be disposed on OCA 218 or in any other suitable location, such as on the lower surface of cover layer 214 (e.g., via lamination). Further, touch sensor 226 may be configured to receive touch input in various areas—for example, the touch sensor 226 may be configured to receive touch input in an area equal to, less than, or greater than active display area 210. Display layer 208 and touch sensor 226, along with other components such as cover layer 214 and OCA 218, may be referred to as a touch-display module (TDM).

Display device 200 may include a ledge gap 228 interposed between cover layer 214 and ledge 204 of chassis 202. To prevent undesired entry of debris and other material into display device 200 through aperture 206, ledge gap 228 may be sealed via a suitable sealant deposited in the gap. In some implementations, ledge gap 228 may be sealed via an adhesive that provides support to components in display device. As an example, FIG. 2 shows an adhesive 230 deposited in ledge gap 228 such that the perimeter portion (e.g., non-active display area 212) of display layer 208 is bonded to an underside 232 of ledge 204 via the adhesive. In this way, ledge 204, and particularly the side edge of the ledge that faces outer edge 216 and the underside 232 of the ledge, may be leveraged to suspend and support components in display device 200, and thereby limit the bezel portion required to support such components, in turn aiding reducing bezel width 224.

Structures may be used to support components in display device 200 alternatively or in addition to the use of adhesive 230. As an example, FIG. 2 shows the inclusion of three compliant supports 234 positioned between display layer 208 and a bottom inner surface 236 of chassis 202. Compliant supports 234 may comprise any suitable material that at least partially absorbs shocks and forces and thereby limits their transfer to display layer 208. Compliant supports 234 may also prevent display layer 208 from downward deflection into bottom inner surface 236 and the damage that might otherwise result to the display layer. Compliant supports 234 may cooperate with adhesive 230 to support display layer 208 and other components in display device 200, or may provide substantially all of the support, for example in implementations in which a sealant is used in lieu of adhesive 230. The use of compliant supports 234 for implementations in which a sealant is used in lieu of adhesive 230 may allow a portion of underside 232 of ledge 204, on which the adhesive would otherwise be deposited, to be eliminated, which may reduce the bezel width of display device 200. While three compliant supports 234 are depicted in FIG. 2, any suitable number may be employed in display device 200. Further, other compliant support configurations are possible—for example, a contiguous compliant support layer underlying the entirety of display layer 208 may be used. Compliant supports 234 may be installed in chassis 202 by any suitable process, including those in which the compliant supports are inserted prior to or after insertion of display layer 208.

While FIG. 2 illustrates the use of a single ledge 204, two or more ledges may be employed in a display device. To this end, FIG. 3 shows a cross-sectional view of a display device 300 comprising an upper ledge 302 surrounding an aperture 304 in and/or through which a cover layer 305, touch sensor 306, an OCA 308, and a display layer 310 may be disposed. As in display device 200, upper ledge 302 may be used to conceal a non-active display area 312 without occluding an active display area 314, both of display layer 310. However, display device 300 also includes a lower ledge 316 that may be used to support display layer 310 and/or other components. As shown in FIG. 2, display layer 310 may be positioned between an underside 318 of upper ledge 302 and lower ledge 316, with the lower ledge providing support at an underside of the display layer. In some examples, lower ledge 316 may provide sufficient support alone to display layer 310 and other components in the TDM, such that neither an adhesive nor compliant supports need be included in display device 300 to support the TDM. The elimination of an adhesive, and resultant alternative use of a sealant, may reduce the bezel width of display device 300 as described above. However, lower ledge 316 may be used to support the TDM in cooperation with an adhesive (not shown in FIG. 3) and/or one or more compliant supports 320.

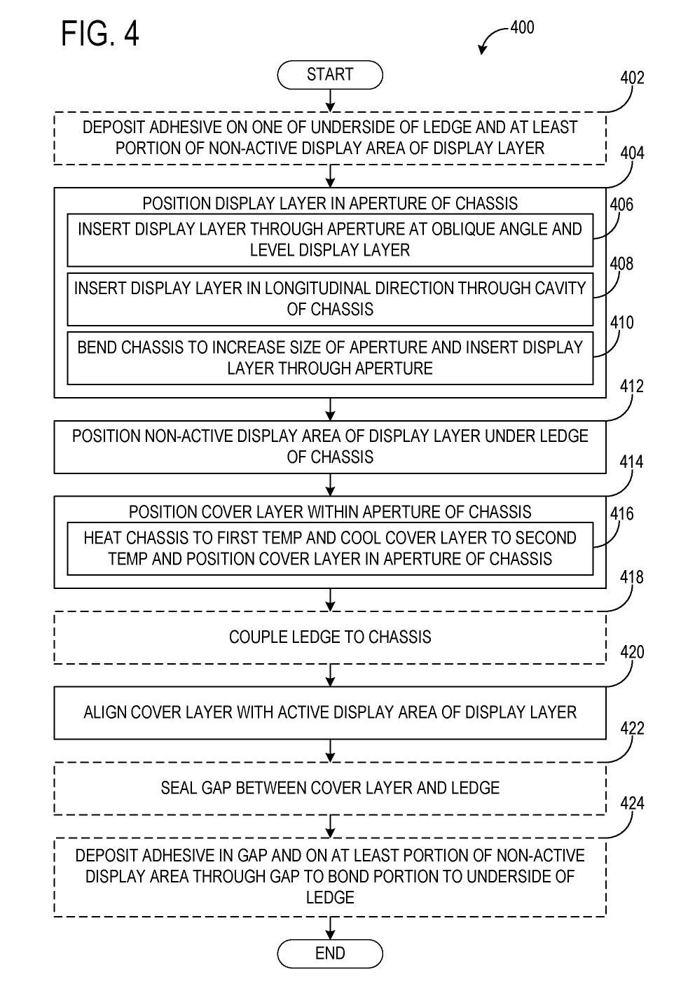

FIG. 4 shows a flowchart illustrating a method 400 of manufacturing a display device. Method 400 may be used to manufacture display device 200 (FIG. 2) and/or display device 300 (FIG. 3), for example.

Method 400 may include, at 402, optionally depositing an adhesive on one of an underside of a ledge and at least a portion of a non-active display area of a display layer. In such an example, the display layer may be attached to the underside of the ledge by placing the non-active display layer in contact with the underside of the ledge through the adhesive.

Method 400 may include, at 404, positioning the display layer in an aperture of a chassis. Positioning the display layer in the aperture of the chassis may include, at 406, inserting the display layer through the aperture at an oblique angle relative to a horizontal axis and a vertical axis of the chassis, and then leveling the display layer. Leveling the display layer may include aligning the display layer with the horizontal axis, for example. Positioning the display layer in the aperture of the chassis may include, at 408, inserting the display layer in a longitudinal direction through a cavity of the chassis. In such an example, the chassis may be formed in separate stages, where the chassis may be initially formed with a cavity through which the display layer, and potentially other components, may be inserted. With the desired components inserted through the cavity, the cavity may be sealed, for example. Positioning the display layer in the aperture of the chassis may include, at 410, bending the chassis to increase a size of the aperture and inserting the display layer through the aperture.

Method 400 may include, at 412, positioning the non-active display area of the display layer under the ledge of the chassis. In this way, the non-active display area and the components therein may be concealed from visual perception.

Method 400 may include, at 414, positioning a cover layer within the aperture of the chassis. Positioning the cover layer within the aperture of the chassis may include, at 416, heating the chassis to a first temperature and cooling the cover layer to a second (e.g., lower) temperature, and, with the chassis at the first temperature and the cover layer at the second temperature, positioning the cover layer in the aperture. In such an approach, the material expansion and contraction of the chassis and cover layer may be leveraged to install the cover layer in the display device.

Method 400 may include, at 418, optionally coupling the ledge to the chassis, for example in implementations in which the ledge is formed separately from the chassis. In alternative implementations, the ledge may be formed integrally with the chassis.

Method 400 may include, at 420, aligning the cover layer with an active display area of the display layer. The cover layer may be aligned with the active display area so that the active display area is fully utilized—e.g., no display elements therein are occluded or otherwise obscured.

Method 400 may include, at 422, optionally sealing a gap between the cover layer and the ledge. A suitable sealant may be used in lieu of an adhesive, for example, if support otherwise afforded to the TDM by the adhesive is unnecessary.

Method 400 may include, at 424, optionally depositing an adhesive in the gap and on at least a portion of the non-active display area of the display layer through the gap to bond the portion of the non-active display area to the underside of the ledge. In this approach, the adhesive may be deposited following insertion of the TDM into the display device, for example as an alternative to earlier deposition of the adhesive at 402 prior to TDM insertion.

Another example provides a display device comprising a chassis including a ledge surrounding an aperture, a cover layer positioned in the aperture, and a display layer attached to the cover layer, the display layer having a perimeter portion extending beyond an outer edge of the cover layer and positioned below an underside of the ledge. In such an example, the perimeter portion may alternatively or additionally be a non-active display area of the display layer. In such an example, the display layer may alternatively or additionally be attached to the cover layer via an optically clear adhesive. In such an example, the display device may alternatively or additionally comprise at least one compliant support positioned between the display layer and a bottom inner surface of the chassis. In such an example, the ledge may alternatively or additionally be an upper ledge, and the display device may alternatively or additionally comprise a lower ledge. In such an example, the display layer may alternatively or additionally be positioned between the underside of the upper ledge and the lower ledge. In such an example, the display device may alternatively or additionally comprise a gap interposed between the cover layer and the ledge. In such an example, the gap may alternatively or additionally have an adhesive deposited therein. In such an example, the perimeter portion of the display layer may alternatively or additionally be bonded to the underside of the ledge via the adhesive. In such an example, the display device may alternatively or additionally comprise a gap interposed between the cover layer and the ledge. In such an example, the gap may alternatively or additionally be sealed via a sealant deposited in the gap. Any or all of the above-described examples may be combined in any suitable manner in various implementations.

Another example provides a method comprising positioning a display layer in an aperture of a chassis, positioning a non-active display area of the display layer under a ledge of the chassis, the ledge defining the aperture, positioning a cover layer within the aperture, and aligning the cover layer with the active display area of the display layer. In such an example, the ledge may alternatively or additionally be formed separately from the chassis and may alternatively or additionally be coupled to the chassis after positioning the display layer in the chassis and the cover layer in the aperture. In such an example, the ledge may alternatively or additionally be formed integrally with the chassis. In such an example, a gap may alternatively or additionally be interposed between the cover layer and the ledge, and the method may alternatively or additionally comprise sealing the gap with a sealant. In such an example, a gap may alternatively or additionally be interposed between the cover layer and the ledge, and the method may alternatively or additionally comprise depositing an adhesive in the gap and on at least a portion of the non-active display area of the display layer through the gap to bond the portion of the non-active display area to an underside of the ledge. In such an example, an adhesive may alternatively or additionally be disposed on one of an underside of the ledge and at least a portion of the non-active display area of the display layer prior to positioning of the display layer in the chassis. In such an example, positioning the display layer in the aperture of the chassis may alternatively or additionally include inserting the display layer through the aperture at an oblique angle relative to a horizontal axis and a vertical axis of the chassis and then leveling the display layer. In such an example, positioning the display layer in the aperture of the chassis may alternatively or additionally include inserting the display layer in a longitudinal direction through a cavity of the chassis, the cavity defined by side walls and a bottom of the chassis. In such an example, positioning the display layer in the aperture of the chassis may alternatively or additionally include bending the chassis to increase a size of the aperture and inserting the display layer through the aperture. In such an example, positioning the cover layer in the aperture may alternatively or additionally include heating the chassis to a first temperature and cooling the cover layer to a second temperature, and, with the chassis at the first temperature and the cover layer at the second temperature, positioning the cover layer in the aperture. Any or all of the above-described examples may be combined in any suitable manner in various implementations.

Another example provides a display device comprising a chassis including a ledge surrounding an aperture, a cover layer positioned in the aperture, an optically clear layer positioned below the cover layer, and a display layer positioned below the optically clear layer, the display layer having a non-active display area extending beyond an outer edge of the cover layer and positioned below an underside of the ledge. In such an example, the display device may alternatively or additionally comprise one or more compliant supports positioned between the display layer and a bottom inner surface of the chassis. In such an example, the ledge may alternatively or additionally be an upper ledge, the chassis may alternatively or additionally include a lower ledge, and the display layer may alternatively or additionally be positioned between the underside of the upper ledge and the lower ledge. Any or all of the above-described examples may be combined in any suitable manner in various implementations.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and nonobvious combinations and subcombinations of the various processes, systems and configurations, and other features, functions, acts, and/or properties disclosed herein, as well as any and all equivalents thereof.

1. A display device, comprising:
a chassis including a ledge surrounding an aperture;
a cover layer positioned in the aperture; and
a display layer attached to the cover layer, the display layer having a perimeter portion extending beyond an outer edge of the cover layer and positioned below an underside of the ledge.

2. The display device of claim 1, where the perimeter portion is a non-active display area of the display layer.

3. The display device of claim 1, where the display layer is attached to the cover layer via an optically clear adhesive.

4. The display device of claim 1, further comprising at least one compliant support positioned between the display layer and a bottom inner surface of the chassis.

5. The display device of claim 1, where the ledge is an upper ledge, the display device further comprising a lower ledge, the display layer positioned between the underside of the upper ledge and the lower ledge.

6. The display device of claim 1, further comprising a gap interposed between the cover layer and the ledge, the gap having an adhesive deposited therein, the perimeter portion of the display layer bonded to the underside of the ledge via the adhesive.

7. The display device of claim 1, further comprising a gap interposed between the cover layer and the ledge, the gap being sealed via a sealant deposited in the gap.

8. A method, comprising:
positioning a display layer in an aperture of a chassis;
positioning a non-active display area of the display layer under a ledge of the chassis, the ledge defining the aperture;
positioning a cover layer within the aperture; and
aligning the cover layer with the active display area of the display layer.

9. The method of claim 8, where the ledge is formed separately from the chassis and is coupled to the chassis after positioning the display layer in the chassis and the cover layer in the aperture.

10. The method of claim 8, where the ledge is formed integrally with the chassis.

11. The method of claim 8, where a gap is interposed between the cover layer and the ledge, the method further comprising sealing the gap with a sealant.

12. The method of claim 8, where a gap is interposed between the cover layer and the ledge, the method further comprising depositing an adhesive in the gap and on at least a portion of the non-active display area of the display layer through the gap to bond the portion of the non-active display area to an underside of the ledge.

13. The method of claim 8, where an adhesive is disposed on one of an underside of the ledge and at least a portion of the non-active display area of the display layer prior to positioning of the display layer in the chassis.

14. The method of claim 8, where positioning the display layer in the aperture of the chassis includes inserting the display layer through the aperture at an oblique angle relative to a horizontal axis and a vertical axis of the chassis and then leveling the display layer.

15. The method of claim 8, where positioning the display layer in the aperture of the chassis includes inserting the display layer in a longitudinal direction through a cavity of the chassis, the cavity defined by side walls and a bottom of the chassis.

16. The method of claim 8, where positioning the display layer in the aperture of the chassis includes bending the chassis to increase a size of the aperture and inserting the display layer through the aperture.

17. The method of claim 8, where positioning the cover layer in the aperture includes heating the chassis to a first temperature and cooling the cover layer to a second temperature, and, with the chassis at the first temperature and the cover layer at the second temperature, positioning the cover layer in the aperture.

18. A display device, comprising:
a chassis including a ledge surrounding an aperture;
a cover layer positioned in the aperture;
an optically clear layer positioned below the cover layer; and
a display layer positioned below the optically clear layer, the display layer having a non-active display area extending beyond an outer edge of the cover layer and positioned below an underside of the ledge.

19. The display device of claim 18, further comprising one or more compliant supports positioned between the display layer and a bottom inner surface of the chassis.

20. The display device of claim 18, where the ledge is an upper ledge, the chassis further including a lower ledge, the display layer positioned between the underside of the upper ledge and the lower ledge.
